(19) United States
(12) Patent Application Publication
(10) Pub. No.: US 2025/0393382 A1
(43) Pub. Date: Dec. 25, 2025

(54) STRETCHABLE THIN FILM TRANSISTOR, STRETCHABLE PANEL, AND ELECTRONIC DEVICE

(71) Applicants: Samsung Electronics Co., Ltd., Suwon-si (KR); POSTECH RESEARCH AND BUSINESS DEVELOPMENT FOUNDATION, Pohang-si (KR); UNIST (ULSAN NATIONAL INSTITUTE OF SCIENCE AND TECHNOLOGY), Ulsan (KR)

(72) Inventors: Gae Hwang LEE, Suwon-si (KR); Jimin KWON, Pohang-si (KR); Yong Young NOH, Pohang-si (KR); Hyun Bum KANG, Suwon-si (KR); Hyung Jun KIM, Suwon-si (KR); Mingyu KIM, Pohang-si (KR); Haksoon JUNG, Pohang-si (KR)

(73) Assignees: Samsung Electronics Co., Ltd., Suwon-si (KR); POSTECH RESEARCH AND BUSINESS DEVELOPMENT FOUNDATION, Pohang-si (KR); UNIST (ULSAN NATIONAL INSTITUTE OF SCIENCE AND TECHNOLOGY), Ulsan (KR)

(21) Appl. No.: 19/237,774

(22) Filed: Jun. 13, 2025

(30) Foreign Application Priority Data
Jun. 20, 2024 (KR) 10-2024-0080521

(51) Int. Cl. H10K 10/46; H10K 10/84; H10K 85/60

(52) U.S. Cl. CPC H10K 10/484; H10K 10/84; H10K 85/60

(57) ABSTRACT

Disclosed are a stretchable thin film transistor, and a stretchable panel and an electronic device including the same, the stretchable thin film transistor including a gate electrode, a semiconductor layer overlapped with the gate electrode, a gate insulating layer between the gate electrode and the semiconductor layer, and a source electrode and a drain electrode electrically connected to the semiconductor layer, wherein the semiconductor layer includes a chalcogen-containing two-dimensional semiconductor material and a substituted or unsubstituted aryl chalcogenol or a derivative thereof.

### CROSS-REFERENCE TO RELATED APPLICATION

This application claims priority to and the benefit of Korean Patent Application No. 10-2024-0080521 filed in the Korean Intellectual Property Office on Jun. 20, 2024, the entire contents of which are incorporated herein by reference.

### BACKGROUND

### 1. Field

A stretchable thin film transistor, a stretchable panel, and an electronic device are related.

### 2. Description of the Related Art

In recent years, research on a stretchable panel, such as a display panel that can be curved, bent, rolled or folded or a wearable sensor array that are attached to a living body or an object, is in progress. Such a stretchable panel may be configured to have stretchability (to be stretched and/or restored) according to motions of the living body or shapes of the object as well as the flexibility of be curved, bent, rolled, and/or folded in a predetermined direction.

### SUMMARY

A stretchable panel, such as a stretchable display panel and/or a wearable sensor array, includes a plurality of pixels (subpixels) and a plurality of thin film transistors for independently switching or driving each pixel (subpixel). In order to implement a stretchable panel, each component that constitutes these thin film transistors should also be flexible and stretchable.

Some example embodiments provide a stretchable thin film transistor that may reduce or prevent electrical performance degradation while ensuring flexibility and stretchability.

Some example embodiments provide a stretchable panel including the stretchable thin film transistor.

Some example embodiments provide an electronic device including the stretchable thin film transistor or the stretchable panel.

According to some example embodiments, a stretchable thin film transistor includes a gate electrode, a semiconductor layer overlapping with the gate electrode, a gate insulating layer between the gate electrode and the semiconductor layer, and a source electrode and a drain electrode electrically connected to the semiconductor layer, wherein the semiconductor layer includes a chalcogen-containing two-dimensional semiconductor material and a substituted or unsubstituted aryl chalcogenol or a derivative thereof.

The chalcogen-containing two-dimensional semiconductor material may include a metal chalcogenide nanoflake.

The metal chalcogenide nanoflake may include a metal element selected from Mo, W, Nb, Ta, Pt, Pd, Co, Cr, Cu, Ni, or a combination thereof and a chalcogen element selected from S, Se, Te, or a combination thereof.

A chalcogen element of the substituted or unsubstituted aryl chalcogenol may be anchored to the metal chalcogenide nanoflake.

The metal chalcogenide nanoflake and the substituted or unsubstituted aryl chalcogenol may be chemically bonded by a shared chalcogen element.

The derivative of the substituted or unsubstituted aryl chalcogenol may include a substituted or unsubstituted aromatic compound derived from the substituted or unsubstituted aryl chalcogenol.

The metal chalcogenide nanoflake may be included in a plurality of metal chalcogenide nanoflakes, and the semiconductor layer may include one or more metal chalcogenide nanoflake monolayers in which the metal chalcogenide nanoflakes are arranged along an in-plane direction relative to the semiconductor layer, and the substituted or unsubstituted aryl chalcogenol or the derivative thereof is disposed at least one of a surface of the metal chalcogenide nanoflake monolayer or between adjacent metal chalcogenide nanoflake monolayers.

At least a portion (e.g., all) of the chalcogen element included in the substituted or unsubstituted aryl chalcogenol may be the same as the chalcogen elements included in the chalcogen-containing two-dimensional semiconductor material.

The substituted or unsubstituted aryl chalcogenol may be represented by Chemical Formula 2A.

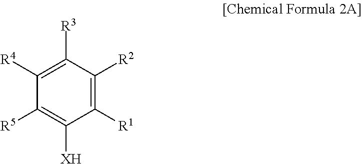

In Chemical Formula 2A,
X is S, Se, or Te, and
R¹ to R⁵ are each independently hydrogen, deuterium, a substituted or unsubstituted C1 to C30 alkyl group, a substituted or unsubstituted C2 to C30 alkenyl group, a substituted or unsubstituted C6 to C30 aryl group, a substituted or unsubstituted C3 to C30 heterocyclic group, a cyano group, a halogen or a combination thereof.

At least one of R¹ to R⁵ in Chemical Formula 2A may include the halogen.

The substituted aryl chalcogenol may include an aryl chalcogenol substituted with one or more halogens.

The gate electrode, the source electrode, and the drain electrode may each independently include a microcrack metal, a liquid metal, a conductive nanostructure, a conductive polymer, or a combination thereof, and the gate insulating layer may include polyorganosiloxane, a polymer including a butadiene structural unit, a polymer including an olefin structural unit, a polymer including a urethane structural unit, a polymer including an acrylic structural unit, or any combination thereof.

According to some example embodiments, a stretchable panel includes a stretchable substrate, a stretchable thin film transistor array on the stretchable substrate and including the stretchable thin film transistor, and a unit element electrically connected to the stretchable thin film transistor and configured to be controlled or driven by the stretchable thin film transistor.

The stretchable panel may further include a non-stretchable pattern overlapping with a portion of the stretchable substrate and having a higher elastic modulus than the stretchable substrate, and the stretchable panel may include a high elastic modulus region in which the non-stretchable pattern is formed, and a low elastic modulus region excluding the high elastic modulus region.

The stretchable substrate may include a polyorganosiloxane, a polymer including a butadiene structural unit, a polymer including an olefin structural unit, a polymer including a urethane structural unit, a polymer including an acrylic structural unit, or a combination thereof, and the non-stretchable pattern may include a polycarbonate, a polymethylmethacrylate, a polyethylene terephthalate, a polyethylene naphthalate, a polyimide, a polyamide, a polyamideimide, a polyethersulfone, or a combination thereof.

The stretchable thin film transistor may be in the high elastic modulus region.

The stretchable thin film transistor may be in the low elastic modulus region.

The unit element may include a light emitting diode, a photoelectric conversion diode, or a combination thereof, and the unit element may be in the high elastic modulus region.

The stretchable panel may be at least one of a stretchable display panel or stretchable sensor array.

According to some example embodiments, an electronic device including the stretchable panel is provided.

Ultra-thin semiconductor layers may ensure flexibility and stretchability while reducing or preventing electrical performance degradation.

### BRIEF DESCRIPTION OF THE DRAWINGS

FIG. 1 is a perspective view showing an example of a stretchable thin film transistor according to some example embodiments,

FIG. 2 is a plan view schematically showing an example of a semiconductor layer of the stretchable thin film transistor of FIG. 1,

FIG. 3 is a cross-sectional view schematically showing an example of a semiconductor layer of the stretchable thin film transistor of FIG. 1,

FIG. 4 is a schematic view exemplarily showing the reaction of surface modification of MoS₂ nanoflakes having chalcogen vacancies (CV) by a surface modifying agent represented by Chemical Formula 2AA,

FIG. 5 is a plan view showing an example of a stretchable panel according to some example embodiments,

FIG. 6 is a cross-sectional view showing an example of a unit element,

FIG. 7 is a plan view showing another example of a stretchable panel according to some example embodiments,

FIG. 8 is a schematic diagram showing a stretchable display panel according to some examples,

FIGS. 9A to 9C are schematic views showing sensor arrays according to some examples,

FIG. 10 is a Raman spectroscopy graph of sample devices according to Preparation Examples and Reference Example,

FIG. 11 is a graph showing the current characteristics of the thin film transistors according to Examples 1 and 2 and Comparative Example 1, and

FIG. 12 is a graph showing the current characteristics of the thin film transistors according to Example 3 and Comparative Example 2.

### DETAILED DESCRIPTION

Hereinafter, some example embodiments will be described in detail so that those of ordinary skill in the art may easily implement them. However, the actually applied structure may be implemented in several different forms and is not limited to the embodiments described herein.

In the drawings, the thickness of layers, films, panels, regions, etc., may be exaggerated for clarity. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

It will be understood that when an element such as a layer, film, region, or substrate is referred to as being “on” another element, it may be directly on the other element or intervening elements may also be present. In contrast, when an element is referred to as being “directly on” another element, there are no intervening elements present. Additionally, spatially relative terms, such as upper, lower, side, etc. are represented based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly.

As used herein, when a definition is not otherwise provided, “substituted” refers to replacement of hydrogen of a compound or a functional group by a substituent selected from deuterium, a halogen atom, a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, sulfonic acid group or a salt thereof, a phosphoric acid group or a salt thereof, a silyl group, a C1 to C20 alkyl group, a C2 to C20 alkenyl group, a C2 to C20 alkynyl group, a C6 to C30 aryl group, C7 to C30 arylalkyl group, C1 to C30 alkoxy group, a C1 to C20 heteroalkyl group, a C3 to C20 heteroaryl group, C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and/or any combination thereof.

Hereinafter, “polymer” includes a homopolymer, a copolymer, and/or any combination thereof.

Hereinafter, “combination” includes a mixture, a composite, and/or a stacked structure of two or more layers.

An example of a stretchable thin film transistor according to some example embodiments is described with reference to the drawings below.

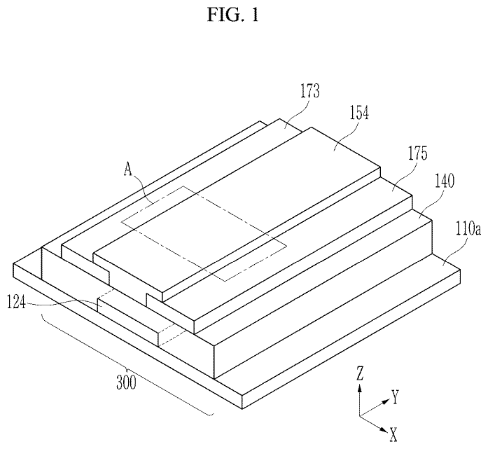

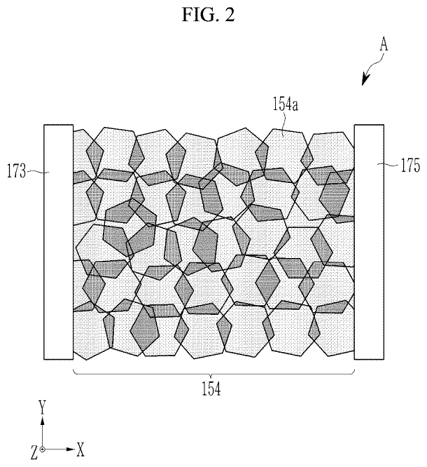

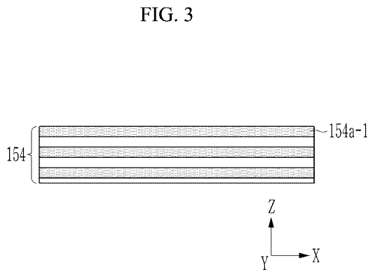

FIG. 1 is a perspective view showing an example of a stretchable thin film transistor according to some example embodiments, FIG. 2 is a plan view schematically showing an example of a semiconductor layer of the stretchable thin film transistor of FIG. 1, and FIG. 3 is a cross-sectional view schematically showing an example of a semiconductor layer of the stretchable thin film transistor of FIG. 1.

Referring to FIG. 1, a stretchable thin film transistor 300 according to some example embodiments includes a gate electrode 124, a gate insulating layer 140, a semiconductor layer 154, a source electrode 173, and a drain electrode 175. The stretchable thin film transistor 300 may be supported by a supporting substrate, and the supporting substrate may be, for example, a stretchable substrate 110a.

The gate electrode 124 is electrically connected to agate line (not shown) that transmits a gate signal and is overlapped with a semiconductor layer 154 and a gate insulating layer 140 to be described later. The gate electrode 124 may include, for example, a stretchable conductor. The stretchable conductor may include, but is not limited to, a metal such as one or more of gold (Au), copper (Cu), nickel (Ni), aluminum (Al), molybdenum (Mo), chromium (Cr), tantalum (Ta), titanium (Ti), and/or an alloy thereof; a conductive nanostructure such as a conductive nanowire or a conductive nanotube; a liquid metal; a conductive polymer; and/or any combination thereof. The metal may have a plurality of microcracks, for example microcracked Au configured to be stretchable (e.g., be configured to undergo non-plastic deform in one or more directions). The gate electrode 124 may be, for example, a stretchable electrode.

The gate insulating layer 140 may be disposed between the gate electrode 124 and the semiconductor layer 154 described later. In other words, the gate insulating layer 140 may electrically insulate the gate electrode 124 from the semiconductor layer 154. The gate insulating layer 140 may be made of an organic insulator, an inorganic insulator, and/or an organic-inorganic insulator, and may include, for example, a stretchable insulator. The gate insulating layer 140 may include, for example, polyorganosiloxane, a polymer including a butadiene structural unit, a polymer including an olefin structural unit, a polymer including a urethane structural unit, a polymer including an acrylic structural unit, and/or any combination thereof. For example, the gate insulating layer 150 may include polydimethylsiloxane (PDMS), styrene-ethylene-butylene-styrene (SEBS), styrene-ethylene-propylene-styrene (SEPS), styrene-butadiene-styrene (SBS), styrene-isobutylene-styrene (SIBS), and/or any combination thereof, but the examples are not limited thereto. The gate insulating layer 140 may have, for example, one layer or two or more layers.

The source electrode 173 is electrically connected to a data line (not shown) that transmits a data signal and faces the drain electrode 175 with a semiconductor layer 154 described later therebetween. The source electrode 173 and the drain electrode 175 may be electrically connected to a semiconductor layer 154 described later.

The source electrode 173 and the drain electrode 175 may include, for example, a stretchable conductor. The stretchable conductor may include, but is not limited to, a metal such as gold (Au), copper (Cu), nickel (Ni), aluminum (Al), molybdenum (Mo), chromium (Cr), tantalum (Ta), titanium (Ti), and/or an alloy thereof; a conductive nanostructure such as a conductive nanowire or a conductive nanotube; a liquid metal; a conductive polymer; or a combination thereof. The metal may have a plurality of microcracks, for example microcracked Au. The source electrode 173 and the drain electrode 175 may each be, for example, stretchable electrodes.

The semiconductor layer 154 may be disposed to be overlapped with the gate electrode 124 and electrically connected to the source electrode 173 and the drain electrode 175, respectively. The semiconductor layer 154 may be a stretchable semiconductor layer, for example, an ultra-thin semiconductor layer having a thickness of several nanometers.

The semiconductor layer 154 includes a two-dimensional semiconductor material. The two-dimensional semiconductor material may be a planar type inorganic semiconductor nanomaterial extending along two axes (e.g., X-axis and Y-axis), for example, a length extending along the X-axis and a width extending along the Y-axis may be significantly larger than a thickness extending along the Z-axis, and for example, the length extending along the X-axis and the width extending along the Y-axis may each be independently tens of nanometers to several micrometers, and the thickness extending along the Z-axis may be several nanometers or less.

The two-dimensional semiconductor material may include, for example, a metal chalcogenide and may include, for example, a transition metal dichalcogenide. The two-dimensional semiconductor material may be in the form of (or include), for example, a two-dimensional nanostructure.

Referring to FIGS. 2 and 3, the semiconductor layer 154 may include metal chalcogenide nanoflakes 154a as a two-dimensional semiconductor material. The metal chalcogenide nanoflakes 154a may be obtained by exfoliating bulk metal chalcogenide crystals, for example, by a mechanical exfoliation method and/or a solution-phase exfoliation method.

A plurality of metal chalcogenide nanoflakes 154a may be arranged side by side along the in-plane direction (XY direction) of the semiconductor layer 154 to form a metal chalcogenide nanoflake monolayer 154a-1. The metal chalcogenide nanoflakes 154a in the metal chalcogenide nanoflakes monolayer 154a-1 may be partially overlapped with adjacent metal chalcogenide nanoflakes 154a. The semiconductor layer 154 may include one or more metal chalcogenide nanoflake monolayers 154a-1, and adjacent metal chalcogenide nanoflake monolayers 154a-1 may be spaced apart from each other by a gap of angstroms to several nanometers.

The metal chalcogenide nanoflake 154a may include at least one transition metal and at least one chalcogen element, and may be represented by, for example, Chemical Formula 1.

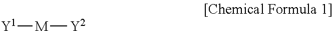

In Chemical Formula 1,
M is the at least one transition metal, for example selected from Mo, W, Nb, Ta, Pt, Pd, Co, Cr, Cu, Ni and/or any combination thereof, and
Y¹ and Y² are the chalcogen elements. Y¹ and Y² may be the same or different chalcogen elements, for example, selected from S, Se, or Te.

The metal chalcogenide nanoflake 154a may for example include MoS₂, MoSe₂, MoSSe, MoSTe, Mo₍₁₋ₓ₎WₓS₂, Mo₍₁₋ₓ₎WₓSe₂, Mo₍₁₋ₓ₎WₓTe₂, Mo₍₁₋ₓ₎NbₓS₂, Mo₍₁₋ₓ₎NbₓSe₂, Mo₍₁₋ₓ₎TaₓS₂, Mo₍₁₋ₓ₎TaₓSe₂, Mo₍₁₋ₓ₎WₓSSe, MoTe₂, WS₂, WSe₂, WSSe, WTe₂, WSTe, W₍₁₋ₓ₎NbₓS₂, W₍₁₋ₓ₎NbₓSe₂, PtS₂, PtSe₂, PtTe₂, PdSe₂, TaS₂, TaSe₂, Ta₍₁₋ₓ₎WₓS₂, Ta₍₁₋ₓ₎WₓSe₂ (wherein 0≤x≤1), and/or any combination thereof, but is not limited thereto.

The semiconductor layer 154 may further include a surface modifying agent or a derivative thereof that may reduce or remove defects at the surface of the metal chalcogenide nanoflakes 154a.

Defects at the surface of metal chalcogenide nanoflakes 154a may mainly occur during the process of preparing the metal chalcogenide nanoflakes 154a from a bulk metal chalcogenide crystal and may include chalcogen vacancies (CV) due to the separation of chalcogen elements in the dispersion process, such as strong ultrasonication during the intercalation and/or exfoliation. These chalcogen vacancies may deform the semiconductor properties of the metal chalcogenide nanoflakes 154a and thus deteriorate the electrical characteristics of the stretchable thin film transistor 300.

The surface modifying agent may effectively modify the chalcogen vacancy sites of the metal chalcogenide nanoflake 154a by reducing or eliminating dangling bonds of the chalcogen vacancy sites of the metal chalcogenide nanoflake 154a.

The surface modifying agent may be an organic compound having a functional group including, for example, a chalcogen element, and the functional group including a chalcogen element may be, for example, a thiol group (—SH), a selenol group (—SeH), a tellurol group (—TeH), and/or any combination thereof. For example, the chalcogen element of the surface modifying agent may be the same as the chalcogen element of the metal chalcogenide nanoflake 154a.

As an example, the surface modifying agent may include a substituted or unsubstituted aryl chalcogenol represented by Chemical Formula 2.

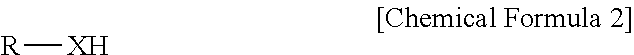

In Chemical Formula 2,
H is hydrogen;
X is a chalcogen element, for example S, Se or Te, and
R is a substituted or unsubstituted C6 to C30 aryl group.

For example, R may be a substituted or unsubstituted phenyl group, a substituted or unsubstituted naphthyl group, a substituted or unsubstituted anthracenyl group, a substituted or unsubstituted phenanthryl group, and/or any combination thereof.

The substituted or unsubstituted aryl chalcogenol may include a functional group (corresponding to —XH in Chemical Formula 2) selected from a thiol group (—SH), a selenol group (—SeH), and/or a tellurol group (—TeH) linked to the bulky substituted or unsubstituted aromatic ring head groups (corresponding to R in Chemical Formula 2), and such a structure may facilitate the separation or detachment of the head group in the reaction of the metal chalcogenide nanoflake 154a and the functional group of the aryl chalcogenol, thereby modifying the chalcogen vacancies of the metal chalcogenide nanoflake 154a. Accordingly, defects caused by chalcogen vacancies in metal chalcogenide nanoflakes 154a may be reduced or eliminated, thereby preventing (or reducing) deformation of the semiconductor characteristics and deterioration of electrical characteristics of the stretchable thin film transistor 300.

According to one or more example embodiments, R may be an aryl group substituted with one or more substituents. For example, R may be an aryl group substituted with deuterium, a substituted or unsubstituted C1 to C30 alkyl group, a substituted or unsubstituted C2 to C30 alkenyl group, a substituted or unsubstituted C6 to C30 aryl group, a substituted or unsubstituted C3 to C30 heterocyclic group, a cyano group, a halogen, and/or any combination thereof. By having an additional substituent other than the aforementioned functional group, the head group may be more easily separated or detached in the reaction between the metal chalcogenide nanoflake 154a and the functional group of the aryl chalcogenol, thereby more effectively modifying the chalcogen vacancies of the metal chalcogenide nanoflake 154a.

For example, R may be an aryl group further substituted with one or more halogens (F, Cl, Br, and/or I). For example, R may be an aryl group substituted with three or more halogens (F, Cl, Br, and/or I), or for example, an aryl group substituted with five or more halogens (F, Cl, Br, and/or I). Due to high electronegativity of the halogen, it may facilitate the separation or detachment of the head group in the reaction of the metal chalcogenide nanoflakes 154a and the functional group of the aryl chalcogenol to modify the chalcogen vacancies of metal chalcogenide nanoflakes 154a more effectively.

For example, R may be an aryl group substituted with one or more C1 to C30 alkyl groups.

As an example, the substituted or unsubstituted aryl chalcogenol may be represented by Chemical Formula 2A.

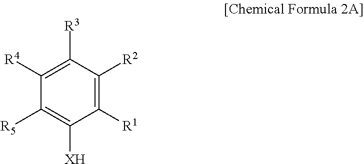

In Chemical Formula 2A,
H is hydrogen,
X is a chalcogen element, for example S, Se or Te, and
R¹ to R⁵ are each independently be hydrogen, deuterium, a substituted or unsubstituted C1 to C30 alkyl group, a substituted or unsubstituted C2 to C30 alkenyl group, a substituted or unsubstituted C6 to C30 aryl group, a substituted or unsubstituted C3 to C30 heterocyclic group, a cyano group, a halogen, and/or any combination thereof.

According to at least some example embodiments, at least one (e.g., one, two, three, four or five) of R¹ to R⁵ may include a halogen (F, Cl, Br, and/or I). For example, at least one (e.g., two, three, four or five) of R¹ to R⁵ may be a halogen element or a C1 to C30 haloalkyl group.

According to at least some example embodiments, each of R¹ to R⁵ may include a halogen (F, Cl, Br, and/or I), and may each independently be F, Cl, Br, I or a C1 to C30 haloalkyl group.

According to at least some example embodiments, at least one of R¹ to R⁵ may be a substituted or unsubstituted C1 to C30 alkyl group. For example, at least one of R¹ to R⁵ may be a methyl group, an ethyl group, a propyl group or a butyl group.

For example, the substituted or unsubstituted aryl chalcogenol may be a compound represented by Chemical Formula 2AA or 2AB, but is not limited thereto.

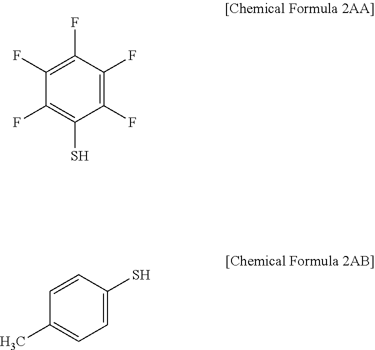

For example, a substituted or unsubstituted aryl chalcogenol may be anchored to a metal chalcogenide nanoflake 154a, and for example, the chalcogen element (X) of the substituted or unsubstituted aryl chalcogenol may be anchored to the metal chalcogenide nanoflake 154a.

For example, the metal chalcogenide nanoflake 154a and a substituted or unsubstituted aryl chalcogenol may be chemically bonded by sharing a chalcogen element (X), wherein the shared chalcogen element may be derived from the substituted or unsubstituted aryl chalcogenol.

For example, the semiconductor layer 154 may further include a derivative of the substituted or unsubstituted aryl chalcogenol, and the derivative of the substituted or unsubstituted aryl chalcogenol may be a reaction byproduct remaining after the reaction of the metal chalcogenide nanoflake 154a described above with the functional group of the aryl chalcogenol. The reaction by-product may be a head group separated or detached from the reaction of the aforementioned metal chalcogenide nanoflake 154a and the functional group of the aryl chalcogenol, and may be a substituted or unsubstituted aromatic compound separated or detached from the functional group used for surface modification in the aforementioned substituted or unsubstituted aryl chalcogenol. For example, the reaction by-products may be a substituted or unsubstituted benzene, a substituted or unsubstituted naphthalene, a substituted or unsubstituted anthracene, a substituted or unsubstituted phenanthrene, and/or any combination thereof.

For example, when a substituted or unsubstituted aryl chalcogenol represented by Chemical Formula 2A is used as a surface modifying agent, the reaction byproduct remaining after the reaction may be a compound represented by Chemical Formula 2A-1.

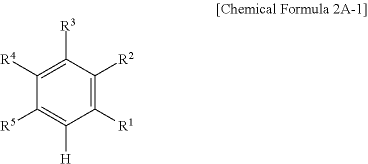

In Chemical Formula 2A-1, R¹ to R⁵ are the same as described above.

For example, when the compound represented by Chemical Formula 2AA is used as a surface modifying agent, the reaction by-product remaining after the reaction may be a compound represented by Chemical Formula 2AA-1, and when a compound represented by Chemical Formula 2AB is used as a surface modifying agent, the reaction by-product remaining after the reaction may be a compound represented by Chemical Formula 2AB-1.

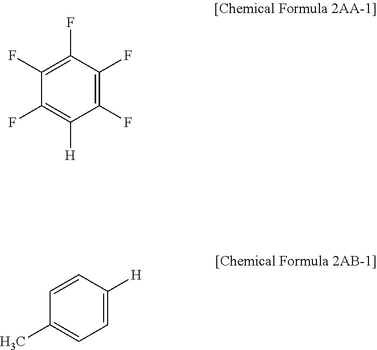

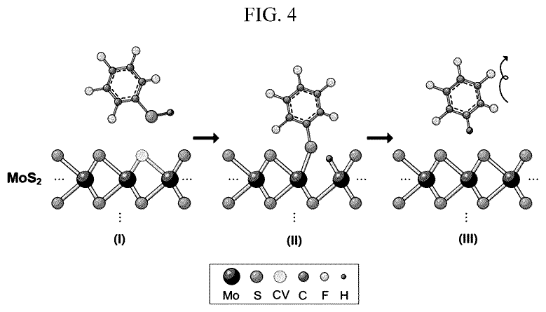

As an example, FIG. 4 is a schematic view showing an exemplary reaction in which MoS₂ nanoflakes having chalcogen vacancies (CV) are surface-modified by a surface modifying agent represented by Chemical Formula 2AA.

Referring to FIG. 4, the MoS₂ nanoflakes 154a may include chalcogen vacancies (CV) generated in a step of preparing MoS₂ nanoflakes from bulk MoS2 crystals (e.g., an intercalation and/or exfoliation), and a solution including a surface modifying agent represented by chemical formula 2AA is supplied to the MoS₂ nanoflakes 154a having the chalcogen vacancies (CV) (step (I)), sulfur (S) of the surface modifying agent may form a covalent bond with a Mo element in a vacancy site of the MoS₂ nanoflakes 154a while hydrogen of a thiol group (—SH) may form a covalent bond with an adjacent Mo element to fill the vacancy site of the MoS₂ nanoflakes 154a (step (II)), and a bulky head group (fluorinated benzene) may be separated or detached from the surface modifying agent by heat treatment such as annealing (step (III)).

The heat treatment may be performed at, for example, a processing temperature of about 100 to about 300° C., and/or within that range, at about 150 to about 250° C.

The fluorinated benzene headgroup separated in step (III) may be a reaction byproduct and may remain in the semiconductor layer 154 and/or may be removed.

By this reaction, the vacancies (defects) of the MoS₂ nanoflakes 154a may be effectively reduced or removed, thereby exhibiting the original semiconductor properties of the MoS₂ nanoflakes 154a, and thus reducing or preventing deterioration of the electrical characteristics of the stretchable thin film transistor 300. Therefore, the stretchable thin film transistor 300 may secure flexibility and stretchability while reducing or preventing deterioration of electrical characteristics by using an ultra-thin two-dimensional semiconductor material in the form of nanoflake.

In FIG. 1, a bottom gate structure thin film transistor is illustrated as an example of an stretchable thin film transistor 300, but the present disclosure is not limited thereto and may be equally applied to a top gate structure in which a gate electrode 124 is arranged on top of a semiconductor layer 154.

The aforementioned stretchable thin film transistors 300 may be repeatedly arranged along rows and/or columns on a stretchable substrate 110a to form a stretchable thin film transistor array, and the stretchable thin film transistor array may be included in a stretchable panel.

A stretchable panel according to some example embodiments is described below.

A stretchable panel according to some example embodiments may include any panel having an array of unit elements including a plurality of unit elements that operate in an active matrix manner arranged on a stretchable substrate that is deformable by an external force, and may include, for example, a flexible display panel, a stretchable display panel, a flexible sensor array panel, a stretchable sensor array panel, and/or any combination thereof, having flexible and/or stretchable characteristics.

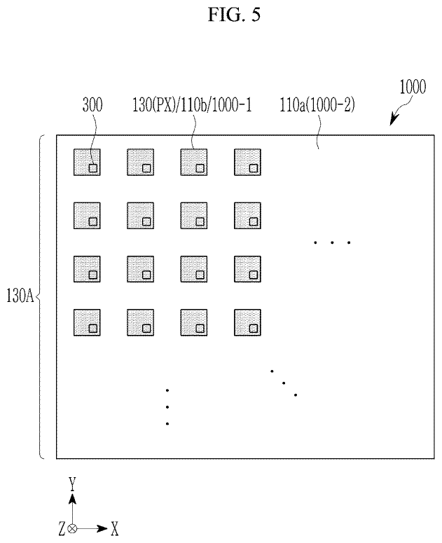

FIG. 5 is a plan view showing an example of a stretchable panel according to some example embodiments.

Referring to FIG. 5, a stretchable panel 1000 according to some example embodiments includes regions having different elastic moduli along an in-plane direction (e.g., XY direction) of a stretchable substrate 110a, and includes a high elastic modulus region 1000-1 having a relatively high elastic modulus and a low elastic modulus region 1000-2 having a relatively low elastic modulus.

The high elastic modulus region 1000-1 may be a region in which resistance to one or more external forces (such as twisting, pressing, pulling, etc.) is relatively high, so that the high elastic modulus region 1000-1 may not be substantially deformed by the external force or a deformation degree may be very small. That is, the high elastic modulus region 1000-1 may include a stretch-resistant region with comparatively low stretchability due to a larger resistance to stretching, in addition to a region with no stretchability at all.

The high elastic modulus region 1000-1 may be a region in which a non-stretchable pattern 110b having a high elastic modulus is covered on a stretchable substrate 110a, and accordingly, the high elastic modulus region 1000-1 may have substantially the same planar shape as the non-stretchable pattern 110b.

The elastic modulus of the high elastic modulus region 1000-1 may be determined by the elastic modulus of the non-stretchable pattern 110b. For example, the elastic modulus of the non-stretchable pattern 110b may be about 100 times or more, within the above range, about 300 times or more, about 500 times or more, or about 1000 times or more, and within the above range, about 100 times to about 108 times, about 500 times to about 108 times, about 1000 times to about 108 times, about 10 times to about 10⁷ times, about 50 times to about 10⁷ times, about 100 times to about 10⁷ times, about 500 times to about 10⁷ times, or about 103 times to about 10⁷ times, higher than that of the stretchable substrate 110a. For example, the elastic modulus of the non-stretchable pattern 110b may be about 10⁴ Pa to about 10¹² Pa, but is not limited thereto. Due to the relatively high elastic modulus of the non-stretchable pattern 110b, the high elastic modulus region 1000-1 may not be substantially stretched or deformed even if the stretchable substrate 110a is stretched in a predetermined direction.

The non-stretchable pattern 110b may include an organic material, an inorganic material, an organic-inorganic material, and/or any combination thereof with a relatively high elastic modulus. For example, the non-stretchable pattern 110b may include polycarbonate, polymethylmethacrylate, polyethyleneterephthalate, polyethylenenaphthalate, polyimide, polyamide, polyamideimide, polyethersulfone, and/or any combination thereof, but the examples not limited thereto.

The non-stretchable pattern 110b may be formed by, for example, coating or depositing a material (e.g., an organic material) with a relatively high elastic modulus on the stretchable substrate 110a and partially removing it by, for example, etching, to leave the non-stretchable pattern 110b only in the portion corresponding to the high elastic modulus region 1000-1. However, the present disclosure is not limited thereto, and the high elastic modulus region 1000-1 and the low elastic modulus region 1000-2 having different elastic moduli may be implemented by forming the non-stretchable pattern 110b on the stretchable substrate 110a in various ways.

The high elastic modulus region 1000-1 may be arranged, for example, along rows and/or columns, and the unit elements 130 described below may be arranged.

The low elastic modulus region 1000-2 is a region that may flexibly respond to external forces such as twisting, pressing, and pulling, and may be a region excluding the high elastic modulus region 1000-1. The low elastic modulus region 1000-2 may be a region where the non-stretchable pattern 110b is not covered on the stretchable substrate 110a and may be relatively evenly arranged on the entire surface of the stretchable panel 1000.

The elastic modulus of the low elastic modulus region 1000-2 may be substantially equal to the elastic modulus of the stretchable substrate 110a. The stretchable substrate 110a may include an elastomer with a relatively low elastic modulus, for example, an elastomer (including organic and inorganic elastomer), an inorganic elastomer-like material, or any combination thereof.

The elastomer may include for example polyorganosiloxane, a polymer including a butadiene structural unit, a polymer including an olefin structural unit, a polymer including a urethane structural unit, a polymer including an acrylic structural unit, or any combination thereof, for example polydimethylsiloxane, thermoplastic polyurethane (TPU), a styrene-ethylene-butylene-styrene (SEBS), styrene-ethylene-propylene-styrene (SEPS), styrene-butadiene-styrene (SBS), styrene-isoprene-styrene (SIS), styrene-isobutyrene-styrene (SIBS), and/or any combination thereof, but is not limited thereto. The inorganic elastomer-like material may include, for example, but not limited to, a ceramic having elasticity, a solid metal, a liquid metal, or any combination thereof. An elastic modulus of the elastomer may be, for example, about 100 Pa to about 10⁹ Pa, but is not limited thereto.

The low elastic modulus region 1000-2 may be surrounded and isolated by the high elastic modulus region 1000-1, but is not limited thereto. Conversely, the high elastic modulus region 1000-1 may be surrounded and isolated by the low elastic modulus region 1000-2.

In the high elastic modulus region 1000-1, a plurality of unit elements 130 are arranged, and the plurality of unit elements 130 may be arranged along rows and/or columns to form a unit element array 130A.

Each unit element 130 may be, for example, a light emitting diode such as an organic light emitting diode, an inorganic light emitting diode, a quantum dot light emitting diode, a micro light emitting diode, a perovskite light emitting diode, a photoelectric conversion diode, an organic photoelectric conversion diode, an inorganic photoelectric conversion diode, an organic/inorganic photoelectric conversion diode, and/or any combination thereof, and may be the same or different from each other.

As an example, each unit element 130 may be a light emitting diode (LED) configured to, independently, emit light of a red spectrum, a green spectrum, a blue spectrum, and/or any combination thereof, but is not limited thereto.

As an example, each unit element 130 may be a photoelectric conversion diode configured to selectively absorb red, green, blue, infrared, or any combination of light and convert the absorbed light into an electrical signal.

As an example, a portion of the unit element 130 may be a light emitting diode and a portion of the unit element 130 may be a photoelectric conversion diode.

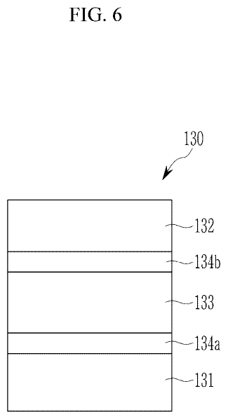

FIG. 6 is a cross-sectional view showing an example of a unit element.

Referring to FIG. 6, the unit element 130 may be a light emitting diode or a photoelectric conversion diode and may include an anode 131; a cathode 132; an active layer 133 between the anode 131 and the cathode 132; and optionally auxiliary layers 134a and 134b between the anode 131 and the active layer 133 and/or between the cathode 132 and the active layer 133.

At least one of the anode 131 or the cathode 132 may be a light transmitting electrode. For example, the anode 131 may be a light transmitting electrode and the cathode 132 may be a reflective electrode. For example, the anode 131 may be a reflective electrode and the cathode 132 may be a light transmitting electrode. For example, the anode 131 and the cathode 132 may each be a light transmitting electrode. At least one of the anode 131 or the cathode 132 may be a stretchable electrode. The stretchable electrode may include, for example, a stretchable conductor or may have a stretchable shape such as a wavy shape, a pleat shape, a pop-up shape, or a non-planar mesh shape. The stretchable electrode may have, for example, a plurality of microcracks, and since the plurality of microcracks are separated from each other like small holes, flexibility may be provided to the stretchable electrode by extending along the stretching direction during stretching while maintaining the electrical movement path in the stretchable electrode.

The active layer 133 may be a light emitting layer or a photoelectric conversion layer.

The light emitting layer may be configured to emit light, e.g., in a red wavelength region, a green wavelength region, a blue wavelength region, an infrared wavelength region, and/or any combination thereof, and may include, for example, an organic light emitting layer, an inorganic light emitting layer (including a quantum dot light emitting layer), an organic/inorganic light emitting layer, or any combination thereof. The light emitting layer may include at least one host material and at least one dopant.

The photoelectric conversion layer may be configured to absorb light, e.g., in a red wavelength region, a green wavelength region, a blue wavelength region, an infrared wavelength region, and/or any combination thereof, and may be configured to convert the absorbed light into an electrical signal, and may be an organic photoelectric conversion layer, an inorganic photoelectric conversion layer, an organic/inorganic photoelectric conversion layer, or any combination thereof. The photoelectric conversion layer may include a p-type semiconductor and an n-type semiconductor, and the p-type semiconductor and the n-type semiconductor may form a p-n junction.

The auxiliary layers 134a and 134b may be, for example, charge auxiliary layers, and may be, for example, a hole transport layer, a hole injection layer, an electron blocking layer, an electron transport layer, an electron injection layer, a hole blocking layer, or any combination thereof, but are not limited thereto.

Each unit element 130 may be configured to be independently controlled and/or driven by one or more thin film transistors, at least some of which may be the aforementioned stretchable thin film transistors 300. For example, the stretchable thin film transistor 300 may be included in each pixel (subpixel) and may be arranged in a high elastic modulus region 1000-1. Each unit element 130 and the stretchable thin film transistor 300 may be electrically connected. The stretchable thin film transistor 300 may be, for example, the stretchable thin film transistor including the semiconductor layer 154 as described above.

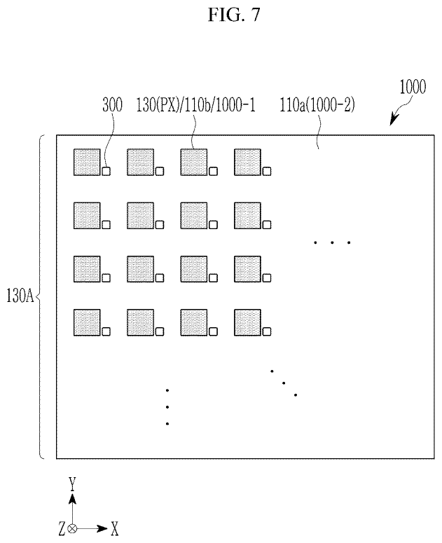

FIG. 7 is a plan view showing another example of a stretchable panel according to some example embodiments.

Referring to FIG. 7, the stretchable panel 1000 according to the present example includes a high elastic modulus region 1000-1 and a low elastic modulus region 1000-2, similar to the above-described example, and the low elastic modulus region 1000-2 may be a region on the stretchable substrate 110a that is not covered with a non-stretchable pattern 110b, and the high elastic modulus region 1000-1 may be a region covered with a non-stretchable pattern 110b. Also, as in the aforementioned example, a plurality of unit elements 130 may be arranged in a high elastic modulus region 1000-1 to form a unit element array 130A, and each pixel (subpixel) may include a thin film transistor electrically connected to each unit element 130, and at least a portion of the thin film transistors may be the aforementioned stretchable thin film transistor 300.

However, unlike the aforementioned example, the stretchable panel 1000 according to the present example may have the stretchable thin film transistor 300 in the low elastic modulus region 1000-2. As described above, the stretchable thin film transistor 300 may include a stretchable electrode, a stretchable insulator, and a stretchable semiconductor layer, so that all components forming the stretchable thin film transistor 300 may be flexibly elongated by an external force and restored.

In this way, by including the aforementioned stretchable thin film transistor 300 as part of the thin film transistor and positioning the stretchable thin film transistor 300 in an area other than the pixel PX (low elastic modulus region 1000-2), the area occupied by the thin film transistor in the pixel PX may be reduced compared to a structure in which all thin film transistors are in each pixel PX.

Therefore, the space limitation of the pixels due to the low elastic modulus region 1000-2 for stretching may be overcome, the pixel size may be reduced, and the number of pixels per unit area may be increased accordingly. For example, the number of pixels per unit area in the stretchable panel 1000 may be greater than or equal to about 150 ppi (pixel per inch), greater than or equal to about 200 ppi, greater than or equal to about 250 ppi, greater than or equal to about 300 ppi, greater than or equal to about 350 ppi, greater than or equal to about 400 ppi, greater than or equal to about 450 ppi, or greater than or equal to about 500 ppi and may be, for example, about 150 ppi to about 1000 ppi, about 200 ppi to about 1000 ppi, about 250 ppi to about 1000 ppi, about 300 ppi to about 1000 ppi, about 350 ppi to about 1000 ppi, about 400 ppi to about 1000 ppi, about 450 ppi to about 1000 ppi, and/or about 500 ppi to about 1000 ppi.

The aforementioned stretchable panel 1000 may be applied to various fields requiring flexibility and/or stretchability, and may be, for example, a stretchable display panel or a stretchable sensor array. The stretchable panel 1000 may be, for example, a bendable display panel, a foldable display panel, a rollable display panel, a wearable device, a skin-type stretchable display panel, a skin-like display panel, a skin-like sensor array, a large-area conformable display, smart clothing, and/or the like, but is not limited thereto.

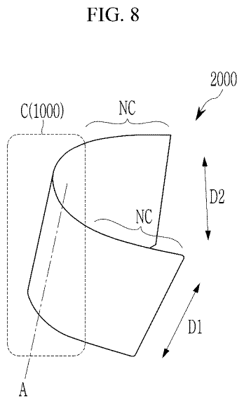

FIG. 8 is a schematic view showing a stretchable display panel according to some examples.

Referring to FIG. 8, the stretchable display panel 2000 according to an example may be a bendable display panel capable of bending the screen along a predetermined direction. The stretchable display panel 2000 may be a display panel flexibly deformed by a user or an external force by introducing a structurally deformable portion into a screen for displaying an image. Herein, the structurally deformable portion may be at least a portion inside the screen.

The stretchable display panel 2000 may be bent along at least one axis A extending in the first direction D1. The stretchable display panel 2000 may include a deformation section (C) that is bent along an axis A and a non-deformable section NC excluding the deformable section C.

The deformable section C may be a bending section that is deformed into a curve around the axis A, and may be included in one or more of the stretchable display panel 2000. The deformable section C may be a region where a radius of curvature (which refers to a degree of being folded, bent, or rolled up to a maximum without substantial damage), is defined and where stress is concentrated, when repetitively folded, bent, or rolled.

The deformable section C of the stretchable display panel 2000 may include the stretchable panel 1000 including the high elastic modulus region 1000-1 and the low elastic modulus region 1000-2.

The high elastic modulus region 1000-1 is a region that is relatively resistant to external forces such as twisting, pressing, and pulling, and is substantially not deformed by the external force or is deformed to a very small degree, and unit elements 130 may be arranged in the high elastic modulus region 1000-1 as described above.

The low elastic modulus region 1000-2 is a region capable of flexibly responding to an external force such as twisting, pressing, and pulling and may include, as described above, an elastomer having a relatively low elastic modulus, and accordingly, may provide the deformable section C of the stretchable display panel 2000 with stretchability to reduce stress acting when repetitively folded, bent, or rolled, and thus prevent or reduce damage in the deformable section C.

At least a portion of the thin film transistors electrically connected to the unit element 130 may be the aforementioned stretchable thin film transistor 300, and the stretchable thin film transistor 300 may be arranged in the high elastic modulus region 1000-1 or the low elastic modulus region 1000-2.

For example, the stretchable thin film transistor 300 may be arranged in the low elastic modulus region 1000-2, and thus, compared to a structure in which all thin film transistors are arranged in each pixel PX, the area occupied by the thin film transistor in the pixel PX may be reduced, thereby overcoming the space limitation of the pixels due to the low elastic modulus region 1000-2 for stretching, reducing the pixel size, and ultimately increasing the number of pixels per unit area. Accordingly, the deformable section C of the stretchable display panel 2000 may realize substantially the same resolution in the non-deformable section NC, and resultantly, uniform display quality over the entire screen may be achieved without deteriorating image quality in the deformable section C such as a bending section.

Unlike the deformable section C, the non-deformable section NC of the stretchable display panel 2000 may not include a separate low elastic modulus region 1000-2 and may include the high elastic modulus region 1000-1. Accordingly, the non-deformable section NC of the stretchable display panel 2000 may be covered with the non-stretchable pattern 110b on the stretchable substrate 110a, and the whole non-deformable section NC may be covered with, for example, a plate-shaped non-stretchable pattern 110b.

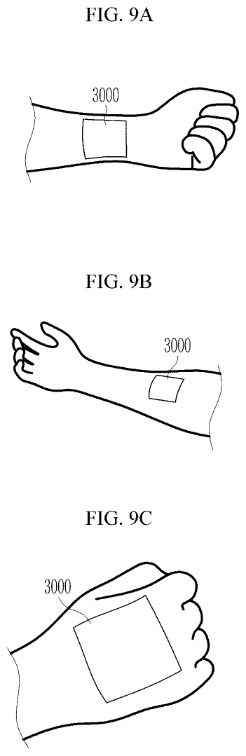

FIGS. 9A to 9C are schematic views showing sensor arrays according to some examples.

Referring to FIGS. 9A to 9C, the sensor array 3000 according to some examples may be an attachable biometric sensor array, and may include the aforementioned stretchable panel 1000. The sensor array 3000 may be attached to a biological surface such as skin, a living body such as an organ, or an indirect means contacting a living body such as clothes to sense and measure biological information such as a biological signal. For example, the biometric sensor array includes an electroencephalogram (EEG) sensor, an electrocardiogram (ECG) sensor, a blood pressure (BP) sensor, an electromyography (EMG) sensor, a blood glucose (BG) sensor, a photoplethysmography (PPG) sensor, an accelerometer, a RFID antenna, an inertial sensor, an activity sensor, a strain sensor, a motion sensor, and/or any combination thereof, but is not limited thereto.

The sensor array 3000 may be attached to a living body in a very thin patch type or band type to monitor biometric information in real time. For example, the skin-type sensor array 3000 may be a sensor array including a photoplethysmography sensor (PPG sensor), and the biometric information may include heart rate, oxygen saturation, stress, arrhythmia, blood pressure, etc., and biometric information may be obtained by analyzing the waveform of an electrical signal.

The aforementioned stretchable panel 1000 and the stretchable display panel 2000 or the sensor array 3000 including the stretchable panel 1000 may be included in various electronic devices, and the electronic device may further include a processor (not shown) and a memory (not shown).

The electronic devices may include, for example, mobile phones, video phones, smart phones, smart pads, smart watches, digital cameras, tablet PCs, laptop PCs, notebook computers, computer monitors, wearable computers, televisions, digital broadcasting terminals, e-books, personal digital assistants (PDAs), PMP (portable multimedia player), EDA (enterprise digital assistant), head mounted displays (HMD), in-vehicle navigations, Internet of Things (IoT), Internet of Everything (IoE), security devices, and medical devices, but are not limited thereto.

Hereinafter, the embodiments are illustrated in more detail with reference to examples. However, these examples are exemplary, and the present scope is not limited thereto.

### Preparation of Two-Dimensional Semiconductor Materials

MoS₂ crystals (2D semiconductor Inc.) are immersed in 40 ml of a tetraethylammonium bromide (TCI, 98%) dispersion (a dispersive medium: anhydrous acetonitrile, 99.8%, Sigma-Aldrich Co., Ltd.), a concentration: 5 mg/ml), and then, a 25 V DC bias is applied thereto for 60 minutes to intercalate tetraethylammonium cations into the MoS₂ crystals. After intercalating the tetraethylammonium cations, the MoS₂ crystals are rinsed with isopropylalcohol (IPA, 99.9%, Daejung Chemicals & Metals) and then, ultrasonicated in anhydrous dimethyl formamide (99.9%, Sigma-Aldrich Co., Ltd.) including polyvinylpyrrolidone (PVP, an average molecular weight 40,000 g/mol, Sigma-Aldrich Co., Ltd.) (40 mL, 8 mg/mL) for 5 minutes. Subsequently, the ultrasonicated dispersion is three times centrifuged at a relative centrifugal force of 50,000 g for 15 minutes to change the solvent to IPA and remove excess PVP or contaminants, preparing a MoS₂ flake dispersion.

### Manufacturing of Sample Devices

### Preparation Example 1

The MoS₂ flake dispersion is dropped onto a silicon wafer on which 20 nanometer (nm) of HfO₂ is formed by using a drop-casting method and then, dried at 200° C. in a nitrogen glove box for 10 minutes to remove the residual solvent and moisture and thereby form an MoS₂ semiconductor layer (MoS₂ nanoplate thickness: 1.99 nm, a tri-layer). Subsequently, the MoS₂ semiconductor layer is immersed in a solution of a surface-modifying agent represented by Chemical Formula 2AA (97 wt %, Signa-Aldrich Co., Ltd., a solvent: IPA) at 50° C. for about one hour and then dried at room temperature to manufacture a sample device including the surface-modified MoS₂ semiconductor layer.

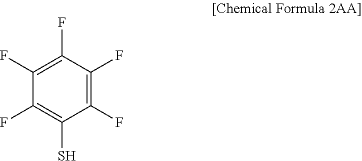 [SMILES: Fc1c(F)c(F)c(S)c(F)c1F]

### Preparation Example 2

The MoS₂ flake dispersion is dropped onto a silicon wafer on which 20 nm of HfO₂ is formed by using a drop-casting method and then, dried at 200° C. in a nitrogen glove box for 10 minutes to remove the residual solvent and moisture and thereby, form an MoS₂ semiconductor layer (an MoS₂ nanoplate thickness: 1.99 nm, a trilayer). Next, the MoS₂ semiconductor layer is immersed in a solution of a surface modifying agent represented by Chemical Formula 2AA (97 wt %, Signa-Aldrich Co. Ltd., a solvent: IPA) at 50° C. for about one hour to form a surface-modified MoS₂ semiconductor layer. Subsequently, the surface modified MoS₂ semiconductor layer is annealed at 200° C. for 30 minutes under a nitrogen atmosphere to remove excess molecules and the adsorbed solution, manufacturing a sample device.

### Reference Example 1

The MoS₂ flake dispersion is dropped onto a silicon wafer on which 20 nm of HfO₂ is formed by using a drop-casting method and then, dried at 200° C. in a nitrogen glove box for 10 minutes to remove the residual solvent and moisture and thereby, form an MoS₂ semiconductor layer (an MoS₂ nanoplate thickness: 1.99 nm, a tri-layer), manufacturing a sample device.

### Evaluation I

The sample devices according to Preparation Examples and Reference Example are subjected to Raman spectroscopy analysis.

The Raman spectroscopy analysis is performed by using Alpha300R Plus Confocal Raman microscope (Witec). A 532 nm laser source is used, which is equipped with a beam diameter of 2 μm and grating of 1800 grooves/mm. All the evaluations are performed at room temperature.

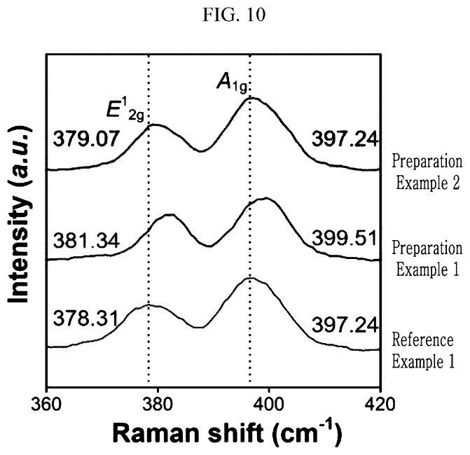

FIG. 10 is a Raman spectroscopy graph of the sample devices according to Preparation Examples and Reference Example.

Referring to FIG. 10, the surface-modified MoS₂ semiconductor layers (Preparation Examples 1 and 2) are confirmed to exhibit different Raman spectral characteristics from the non-surface-modified MoS₂ semiconductor layer (Reference Example 1). Accordingly, the surface-modified MoS₂ semiconductor layers (Preparation Examples 1 and 2) and the non-surface-modified MoS₂ semiconductor layer (Reference Example 1) have different chemical bonds, which suggests that dangling bonds are reduced in sulfur vacancy sites, but new bonds are formed. In addition, the MoS₂ semiconductor layer (Preparation Example 2), in which the annealing is additionally performed after the surface-modification, exhibits a slight shift toward a shorter wavelength (a blue shift from 378.31 cm⁻¹ to 379.07 cm⁻¹), compared with the non-surface-modified MoS₂ semiconductor layer (Reference Example 1), which suggests that a more stable crystal structure is formed by the surface modification and the annealing due to a decrease in local strain.

### Manufacturing of Thin Film Transistor I

### Example 1

Gold (Au) is thermally deposited on a silicon wafer on which 100 nm of SiO₂ is formed to form a gate electrode, and then a SEBS solution (Tuftec H1052, Asahi Kasei Corporation, a concentration of 40 mg/mL in a toluene) is applied and annealed at 100° C. for 0.5 hour to form a gate insulating layer. Then, the MoS₂ flake dispersion obtained above is dropped onto the gate insulating layer using a drop casting method and dried in a nitrogen glove box at 200° C. for 10 minutes to remove residual solvent and moisture, thereby forming a MoS₂ semiconductor layer (MoS₂ nanoplate thickness: 1.99 nm, tri-layer). Next, the MoS₂ semiconductor layer is immersed in a solution of a surface modifying agent (97 wt %, Signa-Aldrich, solvent: IPA) represented by Chemical Formula 2AA at 50° C. for about one hour and dried at room temperature to form a surface-modified MoS₂ semiconductor layer. Subsequently, Au is thermally deposited on the surface-modified MoS₂ semiconductor layer to form source and drain electrodes, thereby manufacturing a thin film transistor.

### Example 2

After Au is thermally deposited on a silicon wafer on which 20 nm of HfO₂ is formed to form a gate electrode, a SEBS solution is applied and annealed at 100° C. for 0.5 hour to form a gate insulating layer. Then, the MoS₂ flake dispersion obtained above is dropped onto the gate insulating layer using a drop casting method and dried in a nitrogen glove box at 200° C. for 10 minutes to remove residual solvent and moisture, thereby forming a MoS₂ semiconductor layer (MoS₂ nanoplate thickness: 1.99 nm, tri-layer). Next, the MoS₂ semiconductor layer is immersed in a solution of a surface modifying agent (97%, Signa-Aldrich, solvent: IPA) represented by Chemical Formula 2AA at 50° C. for about one hour to form a surface-modified MoS₂ semiconductor layer, and then annealed at 200° C. for 30 minutes under a nitrogen atmosphere to remove excess molecules and adsorbed solutions and form a surface-modified MoS₂ semiconductor layer. Subsequently, Au is thermally deposited on the surface-modified MoS₂ semiconductor layer to form source and drain electrodes, thereby manufacturing a thin film transistor.

### Comparative Example 1

Au is thermally deposited on a silicon wafer on which 100 nm of SiO₂ is formed to form a gate electrode, and then a SEBS solution is applied and annealed at 100° C. for 0.5 hour to form a gate insulating layer. Then, the MoS₂ flake dispersion obtained above is dropped onto the gate insulating layer using a drop casting method and dried in a nitrogen glove box at 200° C. for 10 minutes to remove residual solvent and moisture, thereby forming a MoS₂ semiconductor layer (MoS₂ nanoplate thickness: 1.99 nm, tri-layer). Subsequently, Au is thermally deposited on the MoS₂ semiconductor layer to form source and drain electrodes, thereby manufacturing a thin film transistor.

### Evaluation II

The thin film transistor of Examples and Comparative Example are evaluated with respect to electrical characteristics.

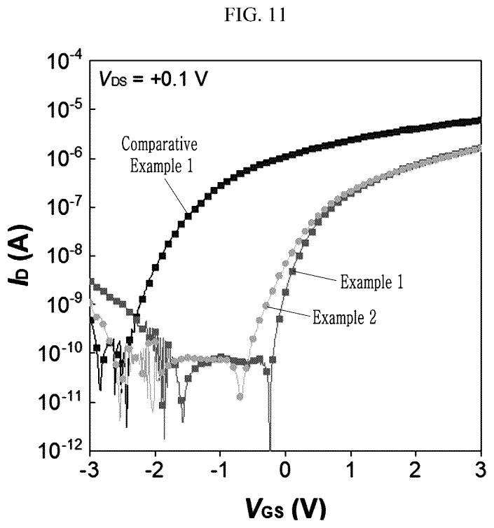

FIG. 11 is a graph showing the current characteristics of the thin film transistors according to Examples 1 and 2 and Comparative Example 1.

Referring to FIG. 11, the thin film transistors of Examples exhibit satisfactory current characteristics according to a voltage, while the thin film transistor of Comparative Example exhibits deteriorated current characteristics.

### Manufacturing of Thin Film Transistor II

### Example 3

Au is thermally deposited on a silicon wafer on which 100 nm of SiO₂ is formed to form source and drain electrodes facing each other. Then, the MoS₂ flake dispersion obtained above is dropped onto the source electrode and the drain electrode by a drop casting method, and dried at 200° C. for 10 minutes in a nitrogen glove box to remove residual solvent and moisture, thereby forming a MoS₂ semiconductor layer. Next, the MoS₂ semiconductor layer is immersed in a solution of a surface modifying agent (97 wt %, Signa-Aldrich, solvent: IPA) represented by Chemical Formula 2AA at 50° C. for about one hour and then dried at room temperature to form a surface-modified MoS₂ semiconductor layer. Subsequently, a SEBS solution is applied on the surface-modified MoS₂ semiconductor layer and annealed at 100° C. for 0.5 hour to form a gate insulating layer. Then, Au is thermally deposited on the gate insulating layer to form a gate electrode, thereby manufacturing a thin film transistor.

### Example 4

Au is thermally deposited on a silicon wafer on which 100 nm of SiO₂ is formed to form source and drain electrodes facing each other. Then, the MoS₂ flake dispersion obtained above is dropped onto the source electrode and the drain electrode by a drop casting method, and dried at 200° C. for 10 minutes in a nitrogen glove box to remove residual solvent and moisture, thereby forming a MoS₂ semiconductor layer. Next, the MoS₂ semiconductor layer is immersed in a solution of a surface modifying agent (97 wt %, Signa-Aldrich, solvent: IPA) represented by Chemical Formula 2AA at 50° C. for about one hour, and then annealed at 200° C. for 30 minutes under a nitrogen atmosphere to remove excess molecules and adsorbed solutions and form a surface-modified MoS₂ semiconductor layer. Subsequently, a SEBS solution is applied on the surface-modified MoS₂ semiconductor layer and annealed at 100° C. for 0.5 hour to form a gate insulating layer. Then, Au is thermally deposited on the gate insulating layer to form a gate electrode, thereby manufacturing a thin film transistor.

### Comparative Example 2

Au is thermally deposited on a silicon wafer on which 100 nm of SiO₂ is formed to form source and drain electrodes facing each other. Then, the MoS₂ flake dispersion obtained above is dropped onto the source electrode and the drain electrode by a drop casting method, and dried at 200° C. for 10 minutes in a nitrogen glove box to remove residual solvent and moisture, thereby forming a MoS₂ semiconductor layer. Subsequently, a SEBS solution is applied on the MoS₂ semiconductor layer and annealed at 100° C. for 0.5 hour to form a gate insulating layer. Then, Au is thermally deposited on the gate insulating layer to form a gate electrode, thereby manufacturing a thin film transistor.

### Evaluation III

The thin film transistors of Examples and Comparative Examples are evaluated with respect to electrical characteristics.

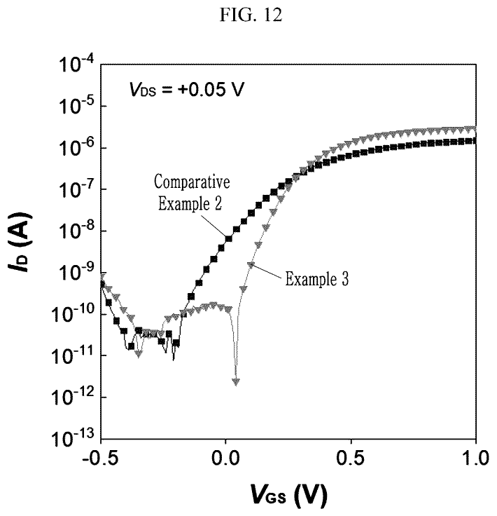

The electrical characteristics are described with reference to FIG. 12 and Table 1.

FIG. 12 is a graph showing the current characteristics of the thin film transistors according to Example 3 and Comparative Example 2.

TABLE 1

| | SS | Nᵢₜ | μₗᵢₙ |
|---|---|---|---|
| | (mV/dec) | (cm⁻²eV⁻¹) | (cm²V⁻¹S⁻¹) |
| Example 4 | 62.0 | 1.46 × 10¹² | 44.5 |
| Comparative Example 2 | 135.4 | 43.08 × 10¹² | 16.7 |

SS: subthreshold swing
Nᵢₜ: interface trap density
μₗᵢₙ: charge mobility

Referring to FIG. 12, the thin film transistor according to Example 3 exhibits satisfactory current characteristics according to a voltage, but the thin film transistor according to Comparative Example 2 exhibits deteriorated current characteristics.

In addition, referring to Table 1, the thin film transistor according to Example 4, compared with the thin film transistor according to Comparative Example 2, exhibits significantly low subthreshold swing (SS) and interface trap density (Nit) but high charge mobility (μₗᵢₙ).

While this disclosure has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A stretchable thin film transistor, comprising
a gate electrode,
a semiconductor layer overlapping with the gate electrode,
a gate insulating layer between the gate electrode and the semiconductor layer, and
a source electrode and a drain electrode electrically connected to the semiconductor layer,
wherein the semiconductor layer includes
a chalcogen-containing two-dimensional semiconductor material, and
a substituted or unsubstituted aryl chalcogenol or a derivative thereof.

2. The stretchable thin film transistor of claim 1, wherein the chalcogen-containing two-dimensional semiconductor material comprises a metal chalcogenide nanoflake.

3. The stretchable thin film transistor of claim 2, wherein the metal chalcogenide nanoflake comprises
a metal element selected from Mo, W, Nb, Ta, Pt, Pd, Co, Cr, Cu, Ni, or a combination thereof, and
a chalcogen element selected from S, Se, Te, or a combination thereof.

4. The stretchable thin film transistor of claim 2, wherein a chalcogen element of the substituted or unsubstituted aryl chalcogenol is anchored to the metal chalcogenide nanoflake.

5. The stretchable thin film transistor of claim 2, wherein the metal chalcogenide nanoflake and the substituted or unsubstituted aryl chalcogenol are chemically bonded by a shared chalcogen element.

6. The stretchable thin film transistor of claim 2, wherein the derivative of the substituted or unsubstituted aryl chalcogenol comprises a substituted or unsubstituted aromatic compound derived from the substituted or unsubstituted aryl chalcogenol.

7. The stretchable thin film transistor of claim 2, wherein
the metal chalcogenide nanoflake is included in a plurality of metal chalcogenide nanoflakes,
the semiconductor layer comprises one or more metal chalcogenide nanoflake monolayers in which the metal chalcogenide nanoflakes are arranged along an in-plane direction relative to the semiconductor layer, and
the substituted or unsubstituted aryl chalcogenol or the derivative thereof is disposed at least one of a surface of one of the one or more metal chalcogenide nanoflake monolayers or between adjacent metal chalcogenide nanoflake monolayers.

8. The stretchable thin film transistor of claim 1, wherein at least a portion of chalcogen elements included in the substituted or unsubstituted aryl chalcogenol is the same as the chalcogen elements included in the chalcogen-containing two-dimensional semiconductor material.

9. The stretchable thin film transistor of claim 1, wherein the substituted or unsubstituted aryl chalcogenol is represented by Chemical Formula 2A: 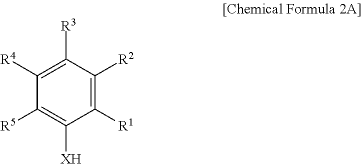
wherein, in Chemical Formula 2A,
X is S, Se, or Te, and
R¹ to R⁵ are each independently hydrogen, deuterium, a substituted or unsubstituted C1 to C30 alkyl group, a substituted or unsubstituted C2 to C30 alkenyl group, a substituted or unsubstituted C6 to C30 aryl group, a substituted or unsubstituted C3 to C30 heterocyclic group, a cyano group, a halogen, or a combination thereof.

10. The stretchable thin film transistor of claim 9, wherein at least one of R¹ to R⁵ in Chemical Formula 2A comprises the halogen.

11. The stretchable thin film transistor of claim 1, wherein the substituted aryl chalcogenol comprises an aryl chalcogenol substituted with one or more halogens.

12. The stretchable thin film transistor of claim 1, wherein
the gate electrode, the source electrode, and the drain electrode each independently comprise a microcrack metal, a liquid metal, a conductive nanostructure, a conductive polymer, or a combination thereof, and
the gate insulating layer comprises polyorganosiloxane, a polymer including a butadiene structural unit, a polymer including an olefin structural unit, a polymer including a urethane structural unit, a polymer including an acrylic structural unit, or a combination thereof.

13. A stretchable panel comprising:
a stretchable substrate; and
a stretchable thin film transistor array on the stretchable substrate, the stretchable thin film transistor array comprising
the stretchable thin film transistor according to claim 1, and
a unit element electrically connected to the stretchable thin film transistor, the unit element configured to be controlled or driven by the stretchable thin film transistor.

14. The stretchable panel of claim 13, further comprising
a non-stretchable pattern overlapping with a portion of the stretchable substrate, the non-stretchable pattern having a higher elastic modulus than the stretchable substrate,
wherein the stretchable panel comprises
a high elastic modulus region in which the non-stretchable pattern is formed, and
a low elastic modulus region excluding the high elastic modulus region.

15. The stretchable panel of claim 14, wherein
the stretchable substrate comprises a polyorganosiloxane, a polymer including a butadiene structural unit, a polymer including an olefin structural unit, a polymer including a urethane structural unit, a polymer including an acrylic structural unit, or a combination thereof, and
the non-stretchable pattern comprises a polycarbonate, a polymethylmethacrylate, a polyethylene terephthalate, a polyethylene naphthalate, a polyimide, a polyamide, a polyamideimide, a polyethersulfone, or a combination thereof.

16. The stretchable panel of claim 14, wherein the stretchable thin film transistor is in the high elastic modulus region.

17. The stretchable panel of claim 14, wherein the stretchable thin film transistor is in the low elastic modulus region.

18. The stretchable panel of claim 14, wherein
the unit element comprises a light emitting diode, a photoelectric conversion diode, or a combination thereof, and
the unit element is in the high elastic modulus region.

19. The stretchable panel of claim 13, wherein the stretchable panel is at least one of a stretchable display panel or a stretchable sensor array.

20. An electronic device comprising the stretchable panel according to claim 13.
